(19) United States
(12) Patent Application Publication
(10) Pub. No.: US 2025/0344334 A1
(43) Pub. Date: Nov. 6, 2025

(54) BRACKET STRUCTURE

(71) Applicant: LITE-ON TECHNOLOGY CORPORATION, Taipei (TW)

(72) Inventors: Hung-Chi HSU, Taipei (TW); Zheng-Zong Chen, Taipei (TW); Yun-Jhong Lee, Taipei (TW)

(21) Appl. No.: 18/967,699

(22) Filed: Dec. 4, 2024

Related U.S. Application Data
(60) Provisional application No. 63/641,967, filed on May 3, 2024.

(30) Foreign Application Priority Data
Aug. 26, 2024 (TW) 113132066

(51) Int. Cl. H05K 7/14

(52) U.S. Cl. CPC H05K 7/1489

(57) ABSTRACT

A bracket structure is provided. The bracket structure includes a bracket including an accommodating hole, and an elastic piece disposed in the accommodating hole of the bracket. The elastic piece includes a fixed portion, a connection portion, and a movable portion. The connection portion is disposed between the fixed portion and the movable portion. The fixed portion is connected to the bracket. The movable portion includes a first part, a second part and a third part. The first part is connected between the second part and the connection portion. The second part is connected between the first part and the third part. An angle between the first part and the second part is less than 180°. An angle between the second part and the third part is less than 180°.

This application claims the benefit of U.S. provisional application Ser. No. 63/641,967, filed May 3, 2024, and Taiwan application Serial No. 113132066, filed Aug. 26, 2024, the subject matters of which are incorporated herein by reference.

### BACKGROUND

### Technical Field

The present disclosure relates to a bracket structure, and more particularly to a bracket structure for installing an electronic device on a frame.

### Description of the Related Art

Frame that can accommodate multiple electronic devices (such as servers and data storage devices) have been widely used in various industries. In order to install the electronic device on the frame, the size of the frame needs to be compatible with the size of the electronic device. Therefore, the user cannot freely use electronic devices of other sizes, which brings a lot of inconvenience and cannot meet the user's needs.

### SUMMARY

The present disclosure provides a bracket structure that can install an electronic device with a smaller size on a frame with a larger size to solve the problem of incompatibility between the size of the electronic device and the size of the frame. In addition, the bracket structure of the present disclosure can be installed on the frame without tools, can be easily and quickly installed on or removed from the frame, and can reduce costs.

According to some embodiments, a bracket structure is provided. The bracket structure includes a bracket including an accommodating hole, and an elastic piece disposed in the accommodating hole of the bracket. The elastic piece includes a fixed portion, a connection portion, and a movable portion. The connection portion is disposed between the fixed portion and the movable portion. The fixed portion is connected to the bracket. The movable portion includes a first part, a second part and a third part. The first part is connected between the second part and the connection portion. The second part is connected between the first part and the third part. An angle between the first part and the second part is less than 180°. An angle between the second part and the third part is less than 180°.

According to some embodiments, a bracket structure is provided. The bracket structure includes a bracket including an accommodating hole, and an elastic piece disposed in the accommodating hole of the bracket. The elastic piece includes a fixed portion, a connection portion, and a movable portion. The connection portion is for connecting the fixed portion and the movable portion. The fixed portion is connected to the bracket. The movable portion at least includes a first bending structure and a second bending structure. The first bending structure is connected to the connection portion and the second bending structure. An opening of the first bending structure and an opening of the second bending structure face opposite directions.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a schematic view of a bracket structure according to an embodiment of the present disclosure.

FIG. 2 illustrates a schematic exploded view of a bracket structure according to an embodiment of the present disclosure.

FIG. 3 illustrates a schematic view of an elastic piece according to an embodiment of the present disclosure.

FIG. 4 illustrates a partial perspective view of a bracket structure according to an embodiment of the present disclosure.

FIG. 5 illustrates a partial cross-section view of a bracket structure according to an embodiment of the present disclosure.

FIG. 6 illustrates a schematic view of a bracket structure and a frame after installation according to an embodiment of the present disclosure.

FIG. 7 illustrates a schematic view of an elastic piece according to another embodiment of the present disclosure.

FIG. 8 illustrates a schematic view of an elastic piece according to yet another embodiment of the present disclosure.

### DETAILED DESCRIPTION

Various embodiments will be described more fully hereinafter with reference to accompanying drawings. For clarity, the components may not be drawn to scale. The specification and the drawings are to be regarded as an illustrative sense rather than a restrictive sense. The illustration uses the same/similar reference numerals to indicate the same/similar elements. Moreover, use of ordinal terms such as “first”, “second”, “third”, etc., in the specification and claims to modify an element does not by itself imply any priority, precedence, or order of one claim element over another, but are used merely as labels to distinguish one claim element having a certain name from another element having the same name (but for use of the ordinal term) to distinguish the claim elements.

As used in the specification and the appended claims, spatial relation terms such as “on”, “above”, “over”, “upper,” “top”, “below”, “beneath”, “under”, “lower” and “bottom” be used to describe the relative spatial relations or positional relations between one element(s) and another element(s) as illustrated in the drawings, and these spatial relations or positional relations, unless specified otherwise, can be direct or indirect. The spatial relation terms are intended to encompass different orientations of structures in addition to the orientation depicted in the drawings. The structure can be inverted or rotated by various angles, and the spatial relation descriptions used herein can be interpreted accordingly. As used in the specification and the appended claims, the singular forms “a,” “an,” and “the” are intended to include the plural forms as well, unless the context clearly indicates otherwise. As used in the specification and the appended claims, the term “and/or” includes any and all combinations of one or more of the associated listed items.

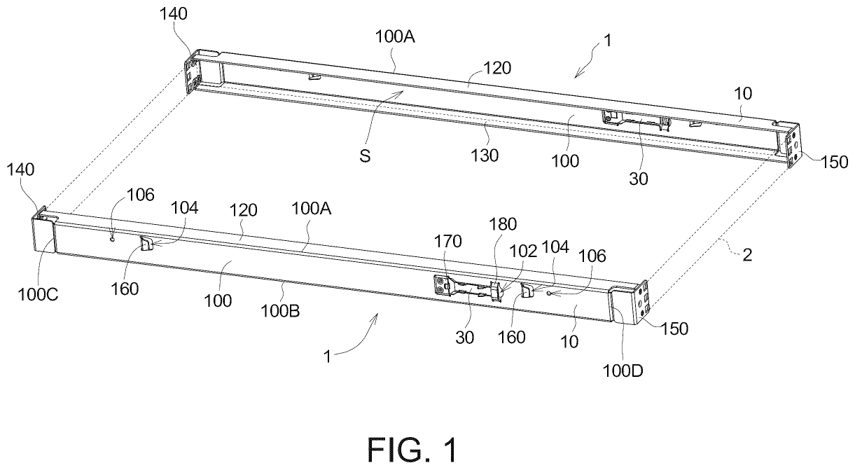

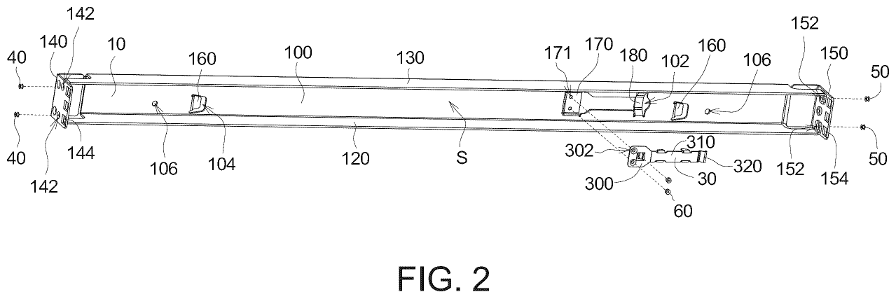

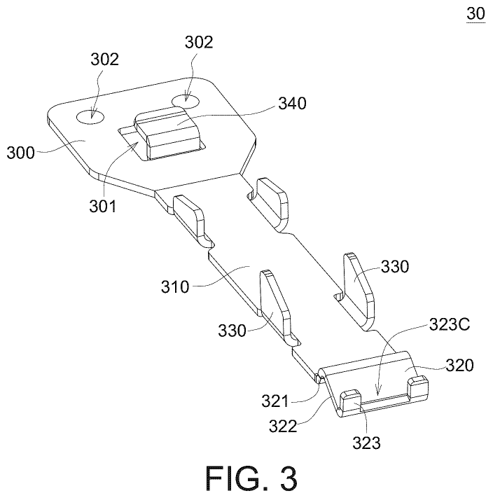

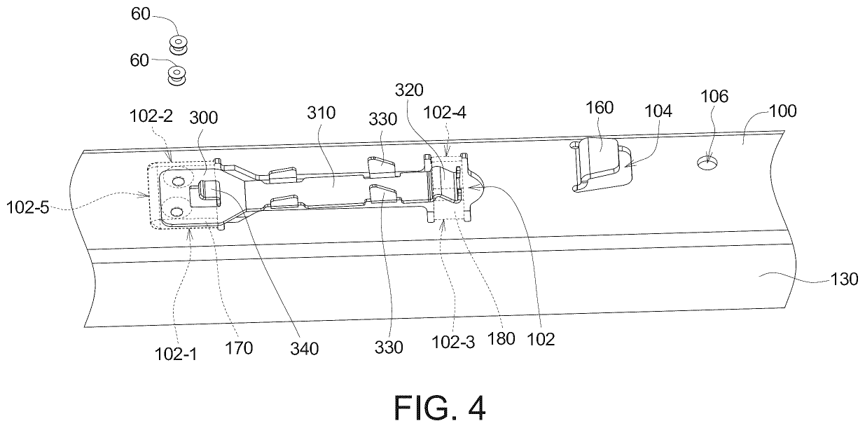

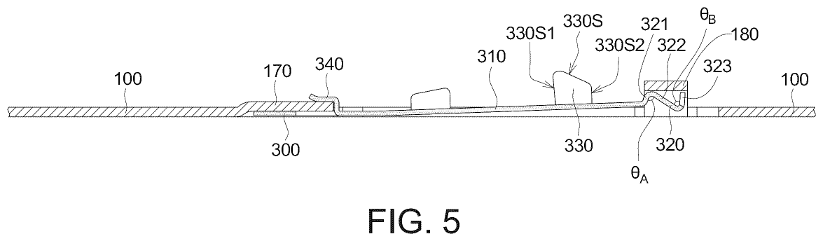

Referring to FIGS. 1 to 5, FIG. 1 illustrates a schematic view of a bracket structure 1 according to an embodiment of the present disclosure, FIG. 2 illustrates a schematic exploded view of the bracket structure 1 of FIG. 1, FIG. 3 illustrates a schematic view of an elastic piece 30 of the bracket structure 1 of FIG. 1, FIG. 4 illustrates a partial perspective view of the bracket structure 1 of FIG. 1, and FIG. 5 illustrates a partial cross-section view of the bracket structure 1 of FIG. 1.

The bracket structure 1 can be used on a frame for installing an electronic device 2 on the frame. For example, the electronic device 2 is a server or data storage device. For example, the frame is a cabinet or a rack. In some embodiments, two bracket structures 1 can be used at the same time, two bracket structures 1 are arranged on opposite sides of the frame, and the electronic device 2 is installed between two bracket structures 1. The electronic device 2 is disposed inside the bracket structure 1, and the outside of the bracket structure 1 can face the frame, and the outside of the bracket structure 1 is opposite to the inside of the bracket structure 1.

The bracket structure 1 includes a bracket 10 and an elastic piece 30. The bracket 10 includes an accommodating hole 102. The elastic piece 30 is disposed in the accommodating hole 102 of the bracket 10. The elastic piece 30 includes a fixed portion 300, a connection portion 310, and a movable portion 320. The connection portion 310 is disposed between the fixed portion 300 and the movable portion 320. The connection portion 310 is for connecting the fixed portion 300 and the movable portion 320. The fixed portion 300 is connected to the bracket 10. The movable portion 320 includes a first part 321, a second part 322 and a third part 323, and can be integrally formed. The first part 321 is disposed between the second part 322 and the connection portion 310. The second part 322 is disposed between the first part 321 and the third part 323. As shown in FIGS. 3 and 5, the first part 321 and the second part 322 can form a first bending structure, that is, an angle θ_{A} between the first part 321 and the second part 322 is less than 180°. In some embodiments, the angle θ_{A} between the first part 321 and the second part 322 can be less than 150°, or can be less than 120°, or can be less than 90°, or can be less than 75°. As shown in FIGS. 3 and 5, the second part 322 and the third part 323 can form a second bending structure, that is, an angle θ_{B} between the second part 322 and the third part 323 is less than 180°. In some embodiments, the angle θ_{B} between the second part 322 and the third part 323 can be less than 150°, or can be less than 120°, or can be less than 90°, or can be less than 75°. The first bending structure can be connected to the connection portion 310 and the second bending structure. The first bending structure formed by the first part 321 and the second part 322, and the second bending structure formed by the second part 322 and the third part 323 may be bent toward different directions. For example, when the elastic piece 30 is disposed in the accommodating hole 102 of the bracket 10, the first bending structure formed by the first part 321 and the second part 322 can be bent away from the outside of the bracket structure 1 or toward the inside of the bracket structure 1; the second bending structure formed by the second part 322 and the third part 323 can be bent toward the outside of the bracket structure 1 or away from the inside of the bracket structure 1. In an embodiment, an opening of the first bending structure and an opening of the second bending structure are oriented in opposite directions. In a side view of the movable portion 320, the movable portion 320 may have an S-shape, a wave-shape, or a Z-shape, as shown in FIG. 5. The third part 323 of the movable portion 320 may include a recess 323C (FIG. 3). When the elastic piece 30 is disposed in the accommodating hole 102 of the bracket 10, an opening of the recess 323C of the third part 323 of the movable portion 320 can face toward the outside of the bracket structure 1. The movable portion 320 is movable relative to the bracket 10. For example, a force can be applied to the movable portion 320 by the user to move the movable portion 320 away from the bracket 10, and the elastic piece 30 deforms at this time; the movable portion 320 can return to its original position, and the elastic piece 30 can return to its original shape once the force applied to the movable portion 320 is removed. In the present specification, the movable portion 320 includes one first bending structure and one second bending structure, but the present disclosure is not limited thereto, the movable portion 320 may include more bending structures.

The fixed portion 300 includes a through hole 301 and a fastening hole 302. The through hole 301 and the fastening hole 302 penetrate the fixed portion 300. The number and the position of the fastening holes 302 are not limited to those show in the illustrations.

The elastic piece 30 includes two guide elements 330 and a coupling element 340. Two guide elements 330 can be disposed on opposite sides of the connection portion 310. The guide element 330 protrudes from the connection portion 310. The guide element 330 includes a side surface 330S1, a side surface 330S2, and an inclined surface 330S connected between the side surface 330S1 and the side surface 330S2. The side surface 330S1 faces the fixed portion 300. The side surface 330S2 faces the movable portion 320. The side surface 330S1 can be opposite to the side surface 330S2. The inclined surface 330S is inclined toward the movable portion 320. The height of the side surface 330S1 may be higher than the height of the side surface 330S2. The side surface 330S1 may be perpendicular to or substantially perpendicular to the surface of the connection portion 310. The side surface 330S2 may be perpendicular to or substantially perpendicular to the surface of the connection portion 310. When the elastic piece 30 is disposed in the accommodating hole 102 of the bracket 10, the guide element 330 protrudes from the accommodating hole 102 and extends toward the outside of the bracket structure 1 (i.e. extends in a direction away from the electronic device 2). The coupling element 340 can be disposed on the fixed portion 300. The coupling element 340 can be disposed on an edge of the through hole 301 of the fixed portion 300. The coupling element 340 protrudes from the fixed portion 300. The coupling element 340 may have a curved structure, such as an L-shaped structure, one side of the L-shaped structure is connected to the fixed portion 300, and the other side of the L-shaped structure extends away from the connection portion 310. An opening of the curved structure may face away from the connection portion 310.

The bracket 10 includes a support plate 100, a side plate 120, a side plate 130, a device fastening structure 140 and a device fastening structure 150. The side plate 120 and the side plate 130 are connected to a side 100A and a side 100B of the support plate 100 respectively. The side 100A is opposite to the side 100B. The device fastening structure 140 and the device fastening structure 150 are connected to a side 100C and a side 100D of the support plate 100 respectively. The side 100C is opposite to the side 100D. The side 100A, the side 100B, the side 100C and the side 100D can be different from each other. The device fastening structure 140 may have a curved structure, such as an L-shaped structure, one side of the L-shaped structure is connected to the side 100C of the support plate 100, and the other side of the L-shaped structure extends toward the inside of the bracket structure 1. The device fastening structure 150 may have a curved structure, such as an L-shaped structure, one side of the L-shaped structure is connected to the side 100D of the support plate 100, and the other side of the L-shaped structure extends toward the inside of the bracket structure 1.

The device fastening structure 140 may include a first mounting hole 142 and a device fastening hole 144. The fastener 40 can fit into the first mounting hole 142. One end of the side plate 120 and one end of the side plate 130 can overlap with the first mounting hole 142 of the device fastening structure 140, and the fastener 40 can pass through the first mounting hole 142 to connect the side plate 120 and the side plate 130 with the device fastening structure 140 (or to fix the side plate 120 and the side plate 130 to the device fastening structure 140). For example, the fastener 40 is a rivet. The connection between the side plate 120, the side plate 130 and the device fastening structure 140 can improve the strength of the bracket 10. A fastening component can fit into the device fastening hole 144. For example, the fastening component is a screw. One end of the electronic device can overlap with the device fastening hole 144 of the device fastening structure 140, and a fastening component that is compatible with the device fastening hole 144 passes through the device fastening hole 144 so that the electronic device can be detachably connected to the device fastening structure 140. The number and the position of the first mounting holes 142 and the device fastening holes 144 are not limited to those shown in the illustrations.

The device fastening structure 150 may include a second mounting hole 152 and a device fastening hole 154. The fastener 50 can fit into the second mounting hole 152. One end of the side plate 120 and one end of the side plate 130 can overlap with the second mounting hole 152 of the device fastening structure 150, and the fastener 50 can pass through the second mounting hole 152 to connect the side plate 120 and the side plate 130 with the device fastening structure 150 (or to fix the side plate 120 and the side plate 130 to the device fastening structure 150). For example, the fastener 50 is a rivet. The connection between the side plate 120, the side plate 130 and the device fastening structure 150 can improve the strength of the bracket 10. A fastening component can fit into the device fastening hole 154. For example, the fastening component is a screw. One end of the electronic device can overlap with the device fastening hole 154 of the device fastening structure 150, and a fastening component that is compatible with the device fastening hole 154 passes through the device fastening hole 154 so that the electronic device can be detachably connected to the device fastening structure 150. The number and the position of the second mounting holes 152 and the device fastening holes 154 are not limited to those shown in the illustrations.

The support plate 100, the side plate 120, the side plate 130, the device fastening structure 140 and the device fastening structure 150 define an accommodating space S. The accommodating space S can be used to accommodate electronic device 2. The support plate 100 of the bracket 10 includes the accommodating hole 102 for accommodating the elastic piece 30. The accommodating hole 102 penetrates the support plate 100 and connects the accommodating space S. In the present embodiment, compared with the side 100C, the accommodating hole 102 is arranged closer to the side 100D, but the present disclosure is not limited thereto. The shape and the size of the accommodating hole 102 can be compatible with the elastic piece 30.

The bracket 10 includes a first limit structure 170 and a second limit structure 180. The first limit structure 170 and the second limit structure 180 are disposed on the support plate 100. The second limit structure 180 may protrude toward a direction away from the accommodation space S, or may protrude toward the outside of the bracket structure 1. The first limit structure 170 and the second limit structure 180 can be disposed across the accommodating hole 102. The first limit structure 170 and the second limit structure 180 may cover different parts of the accommodating hole 102. For example, the first limit structure 170 can extend from an edge 102-1 of the accommodating hole 102 to an edge 102-2 of the accommodating hole 102, and the second limit structure 180 can extend from an edge 102-3 of the accommodating hole 102 to an edge 102-4 of the accommodating hole 102. The edge 102-1 may be opposite to the edge 102-2. The edge 102-3 may be opposite to the edge 102-4. The edge 102-1, the edge 102-2, the edge 102-3 and the edge 102-4 can be different from each other. The first limit structure 170 may include a connection hole 171 penetrating the first limit structure 170. The number and the position of the connection hole 170 are not limited to those show in the illustrations. When the elastic piece 30 is disposed in the accommodating hole 102 of the bracket 10, the first limit structure 170 can cover at least a portion of the fixed portion 300 of the elastic piece 30, the position of the connection hole 171 of the first limit structure 170 may correspond to the position of the fastening hole 302 of the fixed portion 300, the coupling element 340 of the elastic piece 30 may cover a portion of the first limit structure 170, and the second limit structure 180 may cover at least a portion of the movable portion 320 of the elastic piece 30. The fastener 60 can fit into the connection hole 171 of the first limit structure 170 and the fastening hole 302 of the fixed portion 300. The fastener 60 can pass through the connection hole 171 and the fastening hole 302 so that the fixed portion 300 of the elastic piece 30 is fixed to the first limit structure 170 through the fastener 60. The elastic piece 30 can be connected to the bracket 10 through the fastener 60. For example, the fastener 60 is a rivet. In the present embodiment, the first limit structure 170 can be connected to the edge 102-1, the edge 102-2 and the edge 102-5 of the accommodating hole 102, which can improve the connection stability between the elastic piece 30 and the bracket 10. The coupling element 340 of the elastic piece 30 covers the first limit structure 170 to limit movement, which can improve the joint stability of the elastic piece 30 and the bracket 10.

When the elastic piece 30 is disposed in the accommodating hole 102 of the bracket 10, the first bending structure formed by the first part 321 and the second part 322 (having an angle less than) 180° can be bent away from the second limit structure 180, and the second bending structure formed by the second part 322 and the third part 323 (having an angle less than 180°) can be bent toward the second limit structure 180. The opening of the recess 323C of the third part 323 can face the second limit structure 180.

The bracket 10 may include a support hole 106, a penetrating hole 104, a coupling structure 160 disposed on an edge of the penetrating hole 104. The coupling structure 160 may extend from the edge of the penetrating hole 104 toward the center of the penetrating hole 104. The coupling structure 160 may have a curved structure, such as an L-shaped structure, one side of the L-shaped structure is connected to the support plate 100, and the other side of the L-shaped structure extends toward the side 100D of the support plate 100. An opening of the coupling structure 160 and an opening of the coupling element 340 may face opposite directions. The opening of the coupling structure 160 may face the side 100D. The opening of the coupling element 340 may face the side 100C. The coupling structure 160 can be used to install the bracket 10 on the frame. The support hole 106 can be used to install the bracket on the frame. For example, the bracket 10 can be installed on the frame through a fastening component that is compatible with the support hole 106. For example, the fastening component is a screw. Providing the support hole 106 can improve the installation stability between the bracket 10 and the frame. In some embodiment, the bracket 10 does not include the support hole 106.

The bracket 10 can be integrally formed. For example, the bracket 10 can be formed by bending flat sheet metal. In an embodiment, the bracket 10 is made of iron. The elastic piece 30 can be one-piece formed. For example, the elastic piece 30 can be formed by bending flat sheet metal. In an embodiment, the elastic piece 30 is made of stainless steel.

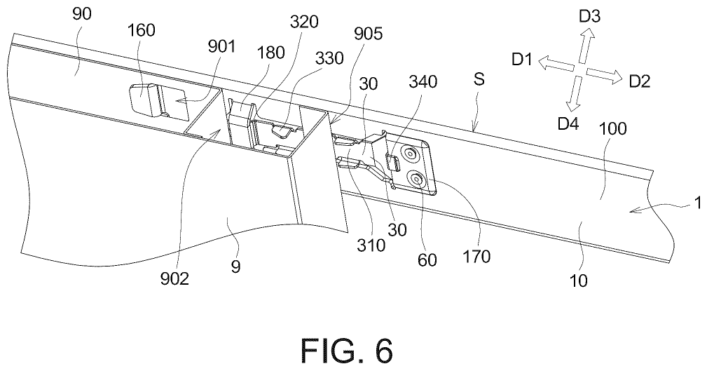

Referring to FIGS. 1 and 6, FIG. 6 illustrates a schematic view of a bracket structure 1 and a frame 9 after installation according to an embodiment of the present disclosure. For example, the frame 9 is a cabinet or a rack. The frame 9 may include column structures 90, and the column structures 90 include positioning holes 901 and gaps 902 near the positioning holes 901. For example, the frame 9 may include four column structures, two column structures among the four column structures are disposed on the first side of the frame 9, and the other 2 column structures among the four column structures are disposed on the second side of the frame 9 opposite to the first side. The bracket structure 1 can be disposed between two column structures on the same side of the frame 9. FIG. 6 shows one of the column structures 90 of the frame 9 to illustrate the installation of the bracket structure 1 and the frame 9. During the process of installing the bracket structure 1 on the frame 9, the coupling structure 160 of the bracket structure 1 passes through the positioning hole 901 of the column structure 90; at this time, the side wall 905 of the column structure 90 exerts force on the guide element 330 of the bracket structure 1 to push the guide element 330, the movable portion 320 and the connection portion 310 of the elastic piece 30 away from the bracket 10; then, the bracket structure 1 is moved along the direction D1 shown in FIG. 6 to make the coupling structure 160 of the bracket structure 1 abut the edge of the positioning hole 901 (as shown in FIG. 6), and the guide element 330 of the elastic piece 30 is located in the gap 902 of the column structure 90. The coupling structure 160 of the bracket structure 1 can be blocked by the positioning hole 901 of the column structure 90, thereby restricting the bracket structure 1 from moving along the directions D3 and D4 shown in FIG. 6 (longitudinal movement), and restricting the bracket structure 1 from moving along the direction D1 shown in FIG. 6 (moving toward the opening of the coupling structure 160) to prevent the electronic device from falling. When the guide element 330 is in the gap 902 of the column structure 90, the force on the guide element 330 exerted by the column structure 90 is removed, the guide element 330, the movable portion 320 and the connection portion 310 return to their original positions, and the elastic piece 30 returns to its original shape. As such, the guide element 330 is blocked by the side wall of the column structure 90, which can restrict the movement of the bracket structure 1 along the direction D2 shown in FIG. 6 and prevent the electronic device from falling.

When uninstalling, the user can apply force on the movable portion 320 of the elastic piece 30 to move the guide element 330, the movable portion 320 and the connection portion 310 of the elastic piece 30 in a direction away from the bracket 10 and make at least a portion of the guide element 330 enter the accommodation space S; the bracket structure 1 is then moved along the direction D2 shown in FIG. 6 until the coupling structure 160 of the bracket structure 1 is completely located in the positioning hole 901, so that the bracket structure 1 can be detached from the frame 9. The inclined surface of the guide element 330 makes the bracket structure 1 easy to uninstall and ensures the blocking when the bracket structure 1 is installed on the frame 9. The bending structures of the movable portion 320 makes it easy for the user to find the place to apply force to operate the elastic piece 30. For example, the user can touch the second part 322 and/or the third part 323 with a finger to make the guide element 330, the movable portion 320 and the connection portion 310 of the elastic piece 30 move in a direction away from the bracket 10. In an embodiment, the user can touch the recess 323C of the elastic piece 30 with a finger to make the guide element 330, the movable portion 320 and the connection portion 310 of the elastic piece 30 move in a direction away from the bracket 10. The recess 323C can enhance the convenience in operation. The bracket structure 1 of the present disclosure can be installed on the frame 9 through the coupling structure 160 without using screws to fix the bracket structure 1. The installation and uninstallation of the bracket structure 1 of the present disclosure can be achieved through pushing the bracket structure 1 without using tools to turn screws. Therefore, the bracket structure 1 of the present disclosure can be installed on or removed from the frame conveniently, simply, and quickly. Moreover, fixing the bracket structure 1 without screws can avoid the problem of missing screws and can reduce costs.

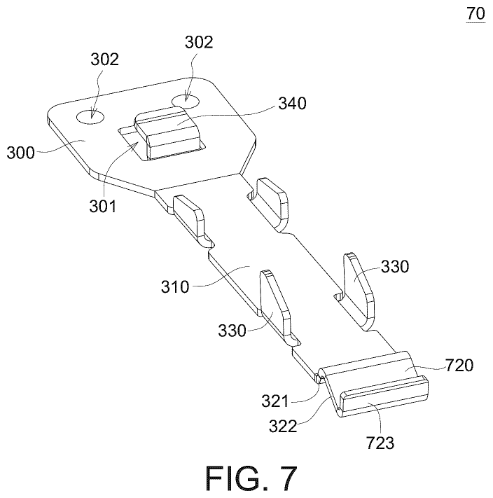

Referring to FIG. 7, FIG. 7 illustrates a schematic view of an elastic piece 70 according to another embodiment of the present disclosure. The difference between the elastic piece 70 and the aforementioned elastic piece 30 is that the movable portion 720 of the elastic piece 70 does not include a recess. The elastic piece 70 includes the fixed portion 300, the connection portion 310, a movable portion 720, a guide element 330 and a coupling element 340. The connection portion 310 is connected between the fixed portion 300 and the movable portion 720. Two guide elements 330 are disposed on opposite sides of the connection portion 310. The coupling element 340 is disposed on the fixed portion 300. The movable portion 720 includes a first part 321, a second part 322 and a third part 723. The first part 321 is connected between the second part 322 and the connection portion 310. The second part 322 is connected between the first part 321 and the third part 723. The third 723 does not include a recess. The third part 723 without the recess can improve the strength and reliability of the elastic piece 70.

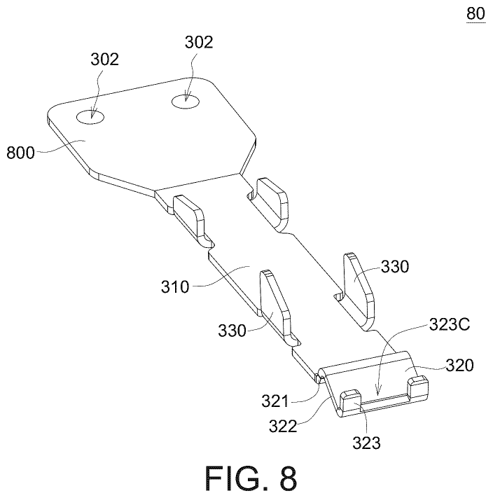

Referring to FIG. 8, FIG. 8 illustrates a schematic view of an elastic piece 80 according to yet another embodiment of the present disclosure. The difference between the elastic piece 80 and the aforementioned elastic piece 30 is that the elastic piece 80 does not include the coupling element 340 and the through hole 301. The elastic piece 80 includes a fixed portion 800, the connection portion 310, the movable portion 320 and a guide element 330. The connection portion 310 is connected between the fixed portion 800 and the movable portion 320. Two guide elements 330 are disposed on opposite sides of the connection portion 310. The fixed portion 800 does not include the through hole 301. Since the fixed portion 800 does not include the through hole 301, the solid part of the fixed portion 800 is increased, which can improve the strength and reliability of the elastic piece 80.

The size of the bracket structure of the present disclosure, the position and specifications of the holes for installation of the bracket structure of the present disclosure (such as the holes used to install the bracket structure on the frame, and the holes used to install electronic device on the bracket structure) can be set according to the common cabinet/rack design guidelines in the industry.

The bracket structure of the present disclosure can be used to install an electronic device on a frame, wherein the size of the electronic device is smaller than the size of the frame. The bracket structure of the present disclosure can solve the problem of incompatibility between the size of the electronic device and the size of the frame. For example, the bracket structure of the present disclosure can be used to install an electronic device smaller than 21 inches on a 21-inch cabinet. In an embodiment, the bracket structure of the present disclosure can be used to install a EIA 19-inch server on an OCP (Open Compute Project) ORV3 cabinet.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A bracket structure, comprising:
a bracket comprising an accommodating hole; and
an elastic piece disposed in the accommodating hole of the bracket, wherein the elastic piece comprises a fixed portion, a connection portion, and a movable portion, the connection portion is disposed between the fixed portion and the movable portion, the fixed portion is connected to the bracket, the movable portion comprises a first part, a second part and a third part, the first part is connected between the second part and the connection portion, the second part is connected between the first part and the third part, an angle between the first part and the second part is less than 180°, and an angle between the second part and the third part is less than 180°.

2. The bracket structure according to claim 1, wherein the movable portion is movable relative to the bracket.

3. The bracket structure according to claim 1, wherein the angle between the first part and the second part is less than 90°, and the angle between the second part and the third part is less than 90°.

4. The bracket structure according to claim 1, wherein the elastic piece comprises two guide elements disposed on opposite sides of the connection portion, each of the guide elements comprises an inclined surface inclined toward the movable portion.

5. The bracket structure according to claim 4, wherein the guide elements protrude from the connection portion and extend toward the outside of the bracket structure.

6. The bracket structure according to claim 1, wherein the bracket comprises a first limit structure disposed on a first edge of the accommodating hole and covering the fixed portion of the elastic piece.

7. The bracket structure according to claim 6, further comprising a fastener, the fixed portion of the elastic piece is fixed to the first limit structure through the fastener.

8. The bracket structure according to claim 7, wherein the elastic piece comprises a coupling element disposed on the fixed portion of the elastic piece, the coupling element protrudes from the fixed portion, and the coupling element covers the first limit structure.

9. The bracket structure according to claim 1, wherein the bracket comprises a second limit structure disposed on a second edge of the accommodating hole and covering the movable portion of the elastic piece.

10. The bracket structure according to claim 9, wherein the first part and the second part form a first bending structure, and the first bending structure is bent away from the second limit structure.

11. The bracket structure according to claim 9, wherein the second part and the third part form a second bending structure, and the second bending structure is bent toward the second limit structure.

12. The bracket structure according to claim 9, wherein the bracket comprises a support plate and two side plates, the side plates are connected to opposite sides of the support plate, the support plate and the side plates define an accommodating space, the accommodating hole penetrates the support plate and connects the accommodating space, and the second limit structure protrudes toward a direction away from the accommodating space.

13. The bracket structure according to claim 1, wherein the third part comprises a recess, an opening of the recess faces toward the outside of the bracket structure.

14. The bracket structure according to claim 1, wherein the bracket is integrally formed.

15. The bracket structure according to claim 1, wherein the bracket comprises a coupling structure, a support plate, two side plates and two device fastening structures, the side plates are connected to a first side and a second side of the support plate respectively, the device fastening structures are connected to a third side and a fourth side of the support plate respectively, the first side is opposite to the second side, the third side is opposite to the fourth side, the first side is different from the third side, the support plate, the side plates and the device fastening structures define an accommodating space, the accommodating hole penetrates the support plate and connects the accommodating space, the coupling structure is disposed on the support plate, the bracket structure is used to install an electronic device on a frame, the electronic device is connected to the device fastening structures and disposed in the accommodating space, the coupling structure passes through a hole of the frame.

16. A bracket structure, comprising:
a bracket comprising an accommodating hole; and
an elastic piece disposed in the accommodating hole of the bracket, wherein the elastic piece comprises a fixed portion, a connection portion, and a movable portion, the connection portion is for connecting the fixed portion and the movable portion, the fixed portion is connected to the bracket, the movable portion at least comprises a first bending structure and a second bending structure, the first bending structure is connected to the connection portion and the second bending structure, and an opening of the first bending structure and an opening of the second bending structure face opposite directions.
